(19) United States
(12) Patent Application Publication
(10) Pub. No.: US 2012/0067408 A1
(43) Pub. Date: Mar. 22, 2012

(54) Sintered CZTS Nanoparticle Solar Cells

(75) Inventors: Charlie Hotz, Mountain View (CA); Margaret Hines, San Jose, CA (US); Donald Zehnder, San Carlos, CA (US); Damoder Reddy, Los Gatos, CA (US); Jing Tang, Sunnyvale, CA (US)

(73) Assignee: SOLEXANT CORP., San Jose, CA (US)

(21) Appl. No.: 12/884,049

(22) Filed: Sep. 16, 2010

(51) Int. Cl. H01L 31/0352; H01B 1/02; H01B 1/12; H01L 31/18

(52) U.S. Cl. 136/255; 438/63; 252/519.51; 252/521.2; 252/520.1; 252/519.2; 257/E31.032; 977/773

(57) ABSTRACT

The present invention discloses an absorber composition and photovoltaic device (PV) using the composition comprising nanoparticles and/or sintered nanoparticles comprising compounds having the formula M^{A}ₓM^{B}_{y}M^{C}_{z}(L^{A}ₐL^{B}_{b})₄ where M^{A}, M^{B} and M^{C} comprise elements chosen from the group consisting of Fe, Co, Ni, Cu, Zn, Cd, Sn and Pb, L^{A} and L^{B} are chalcogens and x is between 1.5 and 2.2, y and z are independently the same or different and are between 0.5 and 1.5 and (a+b)=1.

Particularly preferred synthetic routes to uniform thin films in PV devices comprising sintered nanoparticles of Cu₂ZnSnSe₄ and Cu₂ZnSnS₄ are disclosed.

### BACKGROUND OF THE INVENTION

Thin film photovoltaic devices utilize an absorber layer comprising a semiconductor material to convert sunlight to electricity. Much work and interest has been paid to the classes of compounds known as II-VI, III-V and I-III-VI₂ semiconductor compounds which are the compounds that make up the absorber layer. While these materials have advantages they are not problem free. Various supply issues, toxicity issues (perceived or real) and cost parameters have increased interest in a another material, I₂-II-IV-VI₄ compounds such as Cu₂ZnSnS₄ (CZTS) for use as absorber materials, see for example Todorov et al., High Efficiency Solar Cell with Earth-Abundant Liquid-Processed Absorber, Adv. Mater. (2010), 22, 1-4, the contents of which are incorporated herein by reference.

Many parameters go into making a quality thin film comprising CZTS suitable for use as an absorber layer in a photovoltaic device. Manufacturing thin films (1-10 nm) comprising Cu₂ZnSn(S,Se)₄ is done in the prior art by vacuum deposition, solution processing and particle deposition methods, see Katagiri et al. Thin Solid Films (2009), 517, 2455, Mitzi et al. Thin Solid Films (2009) 517, 2158 and Steinhagen et al. J. Am. Chem. Soc. (2009), 131, 12554 and Guo et al. J. Am. Chem. Soc. (2009) 131, 11672, the contents of all are incorporated herein by reference. These techniques do not satisfactorily provide a cost effective, quality, uniform thin film comprising CZTS suitable for photovoltaic devices. The problems inherent in these processes and their resulting photovoltaic absorber material and devices are discussed herein with examples how the present invention overcomes the prior art limitations.

U.S. Published Application No. 2009314342 A1 discloses solar cells having CZTS as an absorber material; however it is deposited “using established deposition routes such as chemical bath deposition, electrodeposition, physical vapor deposition, evaporation, sputter deposition, chemical vapor deposition or atomic layer deposition”, see paragraph [0026]. Efficiencies of 9.6% have been reported however still greater improvement is desired to compete with other solar technologies having efficiencies approaching 15-30%. By controlling compositional parameters during processing of the nanoparticles used herein and/or employing other embodiments of the invention described herein a novel thin film absorber material suitable for photovoltaic devices is produced, without some of the disadvantages inherent in prior art materials and devices.

Using coordinating solvents and ligands in the synthesis of nanoparticles is well known. The prior art teaches using the chemical properties of ligands to affect nanoparticles within a matrix material in a variety of ways. U.S. Pat. Nos. 6,306,736 and 6,225,198, the contents of which are incorporated herein by reference utilize surfactants to control the shape of nanoparticles. U.S. Pat. No. 7,160,613 uses polydentate ligands to stabilize nanoparticles. While ligand chemistry is widely used in synthesis it is not without its problems. For example the major source of impurities in thin films results from the precursors used synthesizing nanoparticles.

Other prior art attempts to provide a satisfactory CIGS thin film include: U.S. Pat. No. 6,126,740, the contents of which are incorporated herein by reference discloses a CIGS thin film made by dissolving cuprous iodide (CuI), indium iodide (InI₃), gallium iodide (GaI3), and sodium selenide (Na₂Se) into pyridine. Nanoparticles comprising CuInGaSe₂ (CIGS) in mixture with a solvent of pyridine/methanol was sprayed directly onto a molybdenum coated glass substrate heated to 144° C. However, this method requires because pretreatments for deoxidization and dehydration and the whole process should be performed in inert atmosphere. U.S. Published Application 20090139574, the contents of which are incorporated herein by reference discloses a process for producing CuInGaSe₂ in the presence of a selenium compound for the purpose of introducing a capping agent to reduce the likelihood of carbon or other elements contaminating the final film. U.S. Pat. No. 7,663,057, the contents of which are incorporated herein by reference discloses using pyridine as a coordinating ligand and solvent for CuInGaSe₂ synthesis. Prior art uses of electrochemical and chemical-solution deposition to deposit CIGS and CZTS require relatively demanding processing conditions (e.g., high-temperature reactive sintering or the use of harsh chemicals such as hydrazine.) U.S. Pat. No. 7,777,303, the contents of which are incorporated herein by reference discloses Group II-VI nanocrystal/polymer composite materials for solar cells using pyridine.

### SUMMARY OF THE INVENTION

The present invention discloses a solar cell absorber composition comprising nanoparticles, said nanoparticles comprise a compound having the formula M^{A}ₓM^{B}_{y}M^{C}_{z}(L^{A}ₐL^{B}_{b})₄ where M^{A}, M^{B} and M^{C} comprise elements chosen from the group consisting of Fe, Co, Ni, Cu, Zn, Cd, Sn and Pb, L^{A} and L^{B} are chalcogens and x is between 1.5 and 2.2, y and z are independently the same or different and are between 0.5 and 1.5 and (a+b)=1. In one embodiment the nanoparticles comprise a compound having the formula CuₓZn_{y}Sn_{z}(SₐSe_{b})₄ where x/(y+z)=0.7 to 1.2; y/z=0.7 to 1.5 and a+b=1. The nanoparticles may be sintered and the sintered nanoparticles may comprise a compound having the formula Cu₂ZnSnSe₄, Cu₂ZnSnS₄ and Cu₂ZnSnSₓSe₄₋ₓ where 0<x<4, and combinations thereof. In one embodiment the Sn_{Zn} defect centers are less than the Sn_{Cu} defect centers. In another embodiment said nanoparticles comprise a compound having a direct bandgap of about 0.7 to 1.8 eV. The nanoparticles may dispersed in an organic solvent and said dispersion has a viscosity between about 1-100 cP. The nanoparticles may have a ligand attached to the compound and the ligand comprises a compound chosen from the group consisting of alkyl phosphines, alkyl phosphine oxides, alkyl phosphonic acids, or alkyl phosphinic acids, alkyl carboxylic acids, pyridines, cyclic ethers, amines, hydrazine and alkyl hydrazines. Preferably said ligand is pyridine.

In another embodiment there is discloses a photovoltaic device comprising two electrodes, at least one of which is transparent, an absorber layer comprising nanoparticles, and a window layer, said nanoparticles comprise a compound having the formula M^{A}ₓM^{B}_{y}M^{C}_{z}(L^{A}ₐL^{B}_{b})₄ where M^{A}, M^{B} and M^{C} comprise elements chosen from the group consisting of Fe, Co, Ni, Cu, Zn, Cd, Sn and Pb, L^{A} and L^{B} are chalcogens and x is between 1.5 and 2.2, y and z are independently the same or different and are between 0.5 and 1.5 and (a+b)=1. In one embodiment the photovoltaic device comprises a compound having the formula CuₓZn_{y}Sn_{z}(SₐSe_{b})₄ where x/(y+z)=0.7 to 1.2; y/z=0.7 to 1.5 and a+b=1. The nanoparticles may be sintered and the sintered nanoparticles may comprise a compound having the formula Cu₂ZnSnSe₄, Cu₂ZnSnS₄ and Cu₂ZnSnSₓSe₄₋ₓ where 0<x<4, and combinations thereof. In one embodiment the Sn_{Zn} defect centers are less than the Sn_{Cu} defect centers. In another embodiment said photovoltaic device comprises a compound having a direct bandgap of about 0.7 to 1.8 eV. The nanoparticles may be dispersed in an organic solvent and said dispersion has a viscosity between about 1-100 cP. The nanoparticles may have a ligand attached to the compound and the ligand comprises a compound chosen from the group consisting of alkyl phosphines, alkyl phosphine oxides, alkyl phosphonic acids, or alkyl phosphinic acids, alkyl carboxylic acids, pyridines, cyclic ethers, amines, hydrazine and alkyl hydrazines. Preferably said ligand is pyridine.

In another embodiment of the invention there is disclosed a method of making a photovoltaic device, comprising coating a viscous dispersion on a substrate, said viscous dispersion comprises nanoparticles in a solvent, said nanoparticles comprise CuₓE, where x is 1 or 2 and E is S or Se; ZnS and SnEₓ where E is S or Se and x is 1 or 2, and sintering the nanoparticles. In one embodiment ligand is attached to a nanoparticle prior to coating, said ligand chosen from the group consisting of alkyl phosphines, alkyl phosphine oxides, alkyl phosphonic acids, or alkyl phosphinic acids, alkyl carboxylic acids, pyridines, cyclic ethers, amines and hydrazine and alkyl hydrazines. In one embodiment the ligand and the solvent both comprise pyridine. In one embodiment the ligand and said solvent both consist essentially of pyridine. In one embodiment the viscosity of the dispersion is between about 1-100 cP. In one embodiment the nanoparticles are sintered at a temperature of between about 200-600° C. In another embodiment the sintering is done under a selenium atmosphere.

### BRIEF DESCRIPTION OF THE DRAWINGS

FIG. 1 shows a ball and stick figure of CZTS having a kesterite crystal structure.

FIG. 2 shows a general schematic of a side view of a solar cell having a substrate, a back electrode, an absorber layer, a window layer and a TCO layer.

FIG. 3 shows a general schematic of a side view of a solar cell having a substrate, a back electrode, and interface layer, an absorber layer, a window layer and a TCO layer.

### DETAILED DESCRIPTION OF THE EMBODIMENTS

Reference will now be made in detail to some specific embodiments of the invention including the best modes contemplated by the inventors for carrying out the invention. Examples of these specific embodiments are illustrated in the accompanying drawings. While the invention is described in conjunction with these specific embodiments, it will be understood that it is not intended to limit the invention to the described embodiments. On the contrary, it is intended to cover alternatives, modifications, and equivalents as may be included within the spirit and scope of the invention as defined by the appended claims. In the following description, numerous specific details are set forth in order to provide a thorough understanding of the present invention. The present invention may be practiced without some or all of these specific details. In this specification and the appended claims, the singular forms “a,” “an,” and “the” include plural reference unless the context clearly dictates otherwise. Unless defined otherwise, all technical and scientific terms used herein have the same meaning as commonly understood to one of ordinary skill in the art to which this invention belongs. All patents, publications and disclosures disclosed herein are hereby incorporated by reference in their entirety for all purposes.

It is understood that the embodiments described herein are illustrative and not exhaustive examples of the present invention. Intermediate and/or additional layers are contemplated and within the scope of the present invention. Coating, sealing and other structural layers are contemplated where end use of the photovoltaic device warrants such construction.

By “photovoltaic device” it is meant a structure capable of converting light into electricity. In one embodiment the device comprises the following layers which may or may be in this order: a substrate/electrode layer/absorber layer/window layer/TCO layer. This structure is known in the art as a “substrate” configuration solar cell. In another embodiment the photovoltaic device has a “superstrate” configuration and the device comprises the following layers: substrate/TCO/Window layer/absorber layer/electrode layer. It is contemplated that the materials and layers disclosed herein be used in other embodiments such as tandem solar cells.

The absorber layer may comprise one layer or a plurality layers. The absorber layer(s) may comprise a thin film and/or nanoparticles and/or sintered nanoparticles.

The nanoparticles and/or sintered nanoparticles may be chemically treated, for example by ligand exchange to improve/change their solubility, viscosity, sinterability and purity/stoichiometry because some elements from the ligands may become incorporated into the film.

By “solar cell absorber composition” it is meant a composition capable of serving as an absorber material in a photovoltaic device. The composition may comprise a thin film, nanoparticles or sintered nanoparticles or any combination of the three. The bandgap may be between about 0.7 and 1.8. Preferably the composition has a band gap of about 1.0 to about 1.5.

The invention contemplates that there be an interface layer between the absorber layer and the metal electrode layer. Preferably the purpose of such a layer is to provide an ohmic contact. Co-pending and co-assigned U.S. Published Application 20090235986 and co-pending and co-assigned U.S. Ser. No. 12/657,872, the contents of which are incorporated herein by reference disclose interface layers and interface materials suitable for use in the present invention. An “interface layer” includes a single layer as well as a set of multiple layers which may be 1, 2, 3, 4, 5 or more layers. The “interface layer” has been prepared so that the current voltage (I-V) curve of the device is substantially linear and symmetric. If the I-V characteristic is substantially non-linear and asymmetric, the layer can instead be termed a blocking or Schottky contact. Each layer or layers may independently comprise a thin film, nanoparticles, sintered nanoparticles or a combination of one or more of the three. Also, the invention contemplates that a plurality of ohmic contact layers comprising nanoparticles of different chemical compositions can be sequentially deposited. Preferably the interface layer comprises a p-doped metal compound such as Cu doped Mo. Also preferred are metal chalcogen compounds such as MoSe₂ and MoTe₂.

As used herein, the term “chalcogen” means an element of Group 16 of the periodic table. The term “chalcogenide” refers to a compound containing at least one chalcogen and at least one more electropositive element. Preferably, the chalcogen is sulfur or selenium.

“CZTS” means a compound having the formula CuₓZn_{y}Sn_{z}(SₐSe_{b})₄ where x/(y+z)=0.7 to 1.2, preferably 0.8 to 1.1; y/z=0.7 to 1.5, preferably 1.0 to 1.3 and a+b=1. The invention allows for virtually any combination of S/Se ratio in the composition. Strictly speaking a+b≠1 in all situations, allowing for crystal impurities and imperfections.

Nanoparticles and/or sintered nanoparticles useful in the present invention comprise a compound having the formula M^{A}ₓM^{B}_{y}M^{C}_{z}(L^{A}ₐL^{B}_{b})₄ where M^{A}, M^{B} and M^{C} are metals chosen from the group consisting of Sc, Ti, V, Cr, Mn, Fe, Co, Ni, Cu, Zn, Cd, Al, Ga, In, Ge, Sn and Pb more preferably the metals are selected from the group consisting of Fe, Co, Ni, Cu, Zn, Cd, Sn and x is between 1.5 and 2.2, y and z are independently the same or different and are between 0.5 and 1.5 and (a+b)=1. Preferably the compound is Cd free. Even more preferably the nanoparticles and/or sintered nanoparticles used in the present invention comprise a compound having the formula CuₓZn_{y}Sn_{z}(SₐSe_{b})₄ where x/(y+z)=0.7 to 1.2, preferably 0.8 to 1.1; y/z=0.7 to 1.5, preferably 1.0 to 1.3 and a+b=1. In an even more preferred embodiment the nanoparticles and/or sintered nanoparticles comprise a composition selected from the group consisting of Cu₂ZnSnSe₄, Cu₂ZnSnS₄ and Cu₂ZnSnSₓSe₄₋ₓ where 0<x<4, and combinations thereof.

As used herein “capping agent”, “capping ligand”, “ligand” and “surfactant” may be used interchangeably in describing the invention and mean any atom, molecule or other chemical entity attached to or capable of being attached to a nanoparticle of the present invention. Attachment may be by dative bonding, van der waals forces or other force or bond.

According to the present invention nanoparticles may be sintered at a low temperature facilitating roll to roll processing of thin film solar devices. Such techniques are known in the art and disclosed by co-pending and co-assigned U.S. Publication No. 20090223551 A1, the contents of which are incorporated herein by reference. Spherical nanoparticles used herein have a size between about 1-100 nm, preferably 1-50, more preferably between about 2-20 nm. Nanoparticles used herein are not limited to spherical or substantially spherical particles but includes various shaped nanostructures such as tetrapods, dumbbell, bentrod, nanowires, branched and hyper branched structures, nanorods. Also contemplated are hollow particles, homogeneous and heterogeneous nanoparticles. An ink comprising nanoparticles of the present invention may have an increased viscosity according to some embodiments of the present invention. For this purpose the invention prefers non-spherical nanoparticles to increase the viscosity for ink compositions used, for example in slot die coating. In particular it is preferred to use rods and tetrapod shaped nanoparticles. The invention does not require that the nanoparticles be quantum confined. Examples of non-spherical shaped nanoparticles and methods of making them that are suitable for use in the present invention are found in U.S. Pat. Nos. 6,855,202; 7,303,628; 7,311,774 and 7,766,993 the contents of which are all incorporated herein by reference.

The sintering process used herein will alter the morphology, size and shape of the nanoparticles. Nanoparticle layers according to this invention can be sintered in air, an inert atmosphere, an oxidizing or reducing atmosphere, a vacuum or in a Se or S atmosphere to improve their electrical properties, grain size, composition and crystal structure. An oxidizing atmosphere is preferred to improve their electrical properties. Other sintering methods include laser, rapid thermal processing and flash annealing.

Nanoparticles according to this invention are synthesized by injecting semiconductor precursors under conditions that thermodynamically favor crystal growth (i.e. a hot solution at a specific temperature), in the presence of coordinating ligands and/or solvents, which function to kinetically control crystal growth and maintain their size within the quantum-confinement size regime. When heating the reaction medium to a sufficiently high temperature, the precursors dissociate into monomers. Once the monomers in solution reach a high enough supersaturation level, the nanoparticle growth starts with a nucleation process. A coordinating solvent can help control the growth of the nanoparticle. The coordinating solvent is a compound having a one donor pair of electrons available to coordinate to a surface of the growing nanoparticle. Solvent coordination can stabilize the growing nanoparticle. Typical coordinating solvents include alkyl phosphines, alkyl phosphine oxides, alkyl phosphonic acids, or alkyl phosphinic acids, however, other coordinating solvents, such as pyridines, cyclic ethers such as furan, and amines may also be suitable for the nanoparticle production. Examples of suitable coordinating solvents include alkyl carboxylic acids, pyridine, tri-n-octyl phosphine (TOP), tri-n-octyl phosphine oxide (TOPO) and tris-hydroxylpropylphosphine (tHPP).

The nanoparticles are dispersed in a suitable solvent for the particular surfactant on the nanoparticle. Preferably the nanoparticles are dissolved in a solvent of pyridine with an excess of the ligand pyridine, and refluxed at high temperatures. Another chemical treatment is to dissolve the nanoparticles in an excess of the replacement ligand, then precipitate the particles in a solvent for the coordinating solvent, or other synthetic solvent and discard the supernatant after centrifugation. Pyridine, with a boiling point of 116° C. is one of the most facile ligands to displace. In a preferred embodiment nanoparticles are stabilized with pyridine and pyridine is also used as a solvent to wash the nanoparticles. This results in an increased viscosity dispersion of the nanoparticles without the use of binders or other additives. U.S. Pat. No. 7,777,303 discloses

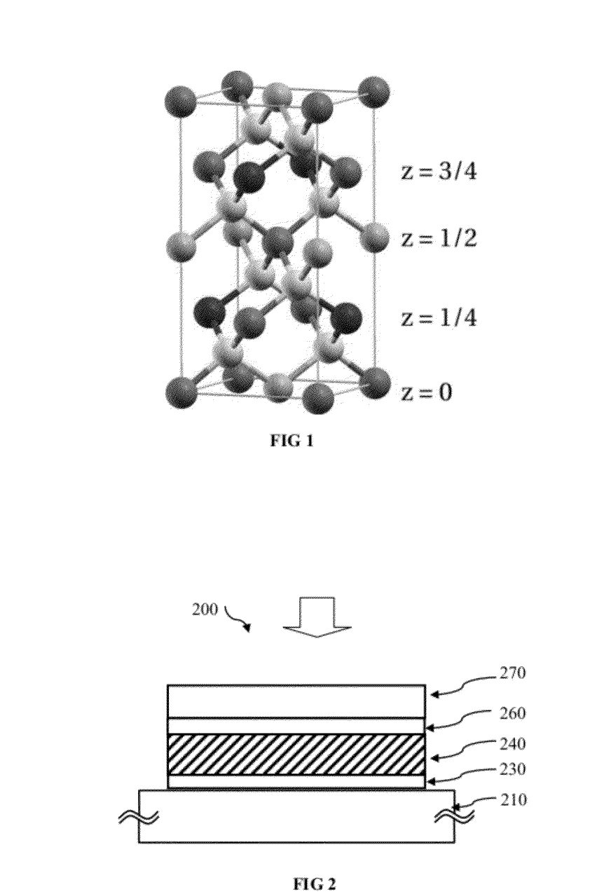

In a preferred embodiment of the present invention absorber compositions comprising CZTS comprise the kesterite crystal structure. An example of this structure is shown in FIG. 1. In this structure, without defects, cations and anions are located in a tetrahedral bonding environment, with a stacking that is similar to zincblende. Other structural modifications are shown in Paier et al. Phys. Rev. B 79, 115126 (2009), the contents of which are incorporated herein by reference. The different structural modifications are related to a different order in the cation sublattice.

Kesterite is characterized by alternating cation layers of CuSn, CuZn, CuSn, and CuZn at z=0, ½, ½, and ¾, respectively. Multivalent semiconductors such as Cu₂ZnSnS₄ contain multivalent elements as part of their skeletal structure and thus have a range of different valence and oxidation states by accommodating a variable number of electrons in nonbonding d-orbitals. Sn has two possible oxidation states +II and +IV. With two oxidation states Cu₂ZnSnS₄ has six possibilities where Sn can exist not only on its crystallographic lattice location in the kesterite structure, but also in some fraction on the Zn or Cu lattice sites. When Sn occupies only the +IV oxidation state on its native site (Sn_{Sn}) or the +II oxidation state on the Cu site (Sn_{Cu}), beneficial electrically active centers are created in the crystal. Conversely, when Sn occupies a Zn site (Sn) there is created the possibility that Sn can change from the +IV oxidation state to the +II oxidation state by photon excitation thus trapping a pair of electrons that will reside in a localized deep trap level instead of occupying the conduction band. This detrimental deep level results in non-radiative recombination of photoexcited electrons and holes and a concomitant reduction in film efficiency, see Biswas et al. “The electronic consequences of multivalent elements in inorganic solar absorbers: Multivalency of Sn in Cu₂ZnSnS₄” Appl. Phys. Lett. 96, 201902 (2010) and also, see Lany et al. J. Appl. Phys. 100, 113725 (2006), the contents of both are incorporated herein by reference. The prior art has sought to minimize the Sn_{Zn} defect centers by appropriate doping principles for CZTS, see Persson et al. Phys Rev. B 72, 035211 (2005) and Zunger et al. Phys. Lett. 83, 57 (2003) the contents of both are incorporated herein by reference. The present invention discloses a method of creating a thin film comprising CZTS having a reduced number of Sn_{Zn} defect centers. Without wishing to be bound by any particular theory or principle it is possible that making nanoparticles using the method described herein results in a lower temperature annealing and does not distort the crystal structure resulting in fewer Sn_{Zn} defect centers.

### [0027] Example 1

### Synthesis of CZTS Nanoparticles

0.52 g (2 mmol) copper(II) acetylacetonate, 0.29 g (1.6 mmol) zinc acetate, 0.18 g (0.8 mmol) SnCl₂. 2H₂O and 0.13 g (4 mmol) S were added to 40 ml oleylamine in a 100 ml three neck flask. The mixture was degassed under vacuum for 2 h, purged with Ar for 30 min at 110 C, heated at 280° C. for 1 h, and then cooled to room temperature. The nanocrystals were collected by precipitation with ethanol followed by centrifugation. The nanocrystals were then washed two more times by redispersion in CHCl₃ and precipitation by ethanol. 10 ml pyridine is added to the final precipitation and refluxed for an extended period of time to replace the original ligand oleylamine. The pyridine exchanged nanoparticles were purified by precipitation with hexane and redispersed in pyridine at a desired concentration to form a viscous ink. The band gap of the CZTS nanoparticles is estimated to be about 1.0 to 1.5. The average composition of the CZTS nanoparticles is determined using EDS. In a preferred method of making nanoparticles various ligands are used to complex with metals during the precipitation process to prevent homogeneous nucleation (precipitation).

### [0028] Example 2

### Solar Cell with CTZS Absorber Layer

In an embodiment of the present invention depicted in FIG. 2 a photovoltaic cell 200 comprises a substrate 210 coated with a metal electrode 220 followed by an absorber layer 240 followed by a window layer 260 and transparent conductor layer 270. Substrate 210 can be an opaque metal foil (molybdenum, stainless steel, aluminum or copper), a flexible transparent polymer film (such as polyimide) or a rigid transparent glass (borosilicate or soda lime). The thickness of the substrate can be 25-250 microns for flexible metal foils, 10-100 microns for flexible polymer films or 1-5 mm for glass. In a substrate configuration the substrate may be transparent or opaque. Metal electrode 220 can be Mo, Ti, Ni, Al, Nb, W, Cr, and Cu as non-limiting examples. Preferred is Mo, Ti or Ni. The metal electrode layer thickness can range from 50 nm to 1,000 nm. The metal layer can be deposited by physical vapor deposition techniques known in the art. In some embodiments of the present invention the substrate and the metal electrode may be the same. A window layer 260 of 10-200 nm, preferably about 60 nm is deposited on top of the absorber layer by the methods well known in the art such as chemical bath deposition (CBD), close space sublimation, vapor transport deposition and sputtering etc. CdS and ZnS are preferred as window layer materials. A transparent conductor layer (TCO) 270 is deposited on top of window layer 260. A 50 nm ZnO layer is deposited followed by a 500 nm Al:ZnO layer. The transparent conductor layer can be 50-1,000 nm comprising ITO or ZnO, combinations thereof or other transparent conductive oxide material known in the art. The TCO layer 270 may be deposited by physical vapor deposition methods well known in the art. The entire device may be subjected to a heat treatment at about 150° C. for up to 40 hours. Nanoparticles made in accordance with Example 1 suspended in pyridine are coated by drop casting. In a preferred embodiment the nanoparticles are coated directly on a Mo foil. Multiple layers are coated until the thickness is about 1-2 μm. Other well known wet coating methods such as spin coating, slot die coating, roll coating, spray coating and ink-jet printing may be used. When using nanoparticles and/or sintered nanoparticles the absorber layer the thickness can be 1-10 microns, preferably about 1-3 microns, even more preferably 1-2 micron. Films are sintered at about 550° C. for 40 minutes in an Argon/Se vapor ambient. Because of their small size nanoparticles exhibit a melting point lower than that of bulk material, see Buffat et al., Size Effect on the Melting Temperature of Gold Particles, Phys. Rev. A, 13, pp 2287-2298 (1976). The lower melting point is a result of comparatively high surface-area-to-volume ratio in nanoparticles, which allows bonds to readily form between neighboring particles. Once the coated nanoparticles are sintered they form a thin film having structural and morphological characteristics comparable to the bulk material. This method circumvents the problems of coating the materials in their molten form and has other advantages over other vacuum based deposition methods such as a layer that is more compositionally uniform and the process is faster and cheaper. Preferably the sintering is accomplished at a temperature between about 200-600° C., more preferably between about 225-550° C. and even more preferably between about 225-300° C. The nitrogen atom on pyridine features a basic lone pair of electrons. Because this lone pair is not delocalized into the aromatic pi-system, pyridine is basic with chemical properties similar to tertiary amines. By replacing the long oleylamine ligand with a shorter ligand pyridine this reduces the amount of bulk material that has to be removed during the sinter process to result in a substantially pure semiconductor. Absorber layer 240 can be chemically etched by methods well known in the art.

### [0029] Example 3

### Formation of a Quinary CZTS Compound Photovoltaic Device

The CZTS nanoparticle films of Example 2 can be selenized to form Cu₂ZnSnS_{y}Se_{1-y}, where 0<y<1 absorbers by annealing the absorber film under Se vapor in a graphite box at temperatures between 400-550° C. For examples of this technique using sulfur see Fernandes et al. Semicond. Sci. Technol. 24 (2009) 105013 (7 pp), the contents of which are incorporated herein by reference The selenized CZTSSe absorber films are processed by the method described in Example 2 to yield photovoltaic devices.

### [0030] Example 4

### Solar Cell with Interface Layer

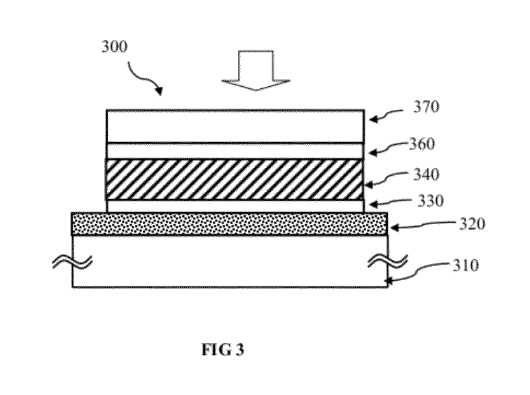

With reference to FIG. 3, a solar cell 300 is constructed comprising a substrate 310 coated with a metal electrode 320 followed by an interface layer 330 followed by an absorber layer 340 then a window layer 360 and transparent conductor layer 370. The layers are similar to those in Example 2. The interface layer may comprise any suitable composition and may be between 0.5 nm and 10 nm thick. The interface layer may also comprise a gradient composition having a material near the back electrode having a larger bandgap than a material closer to the absorber layer. This may be accomplished by coating multilayers of different compositions one upon another.

### [0031] Example 5

### Method of Making Sintered CZTS Nanoparticle Solar Cell

Absorber compositions comprising CZTS may be made by coating precursor nanoparticles on a substrate or metal electrode. Precursor nanoparticles comprising CuₓE, where x is 1 or 2 and E is S or Se; ZnS and SnEₓ where E is S or Se and x is 1 or 2 are synthesized as described below in amounts calculated to synthesize the desired stoichiometric CZTS nanoparticles described herein. The precursors are capped with ligands described herein. Pyridine is a preferred capping agent or ligand. The nanoparticles are dissolved in a solution of pyridine (used as a solvent and capping agent) to having to a viscosity of between 1 and 100, preferably 5-50 more preferably 5-20. Methods for making suitable precursor nanocrystals for this invention include a hot-injection solution synthesis which involves injecting a cold solution of precursors into a hot surfactant solution, leading to the nucleation and growth of nanocrystals. This method provides good control over composition and morphology. Methods for making nanocrystals suitable for use herein are disclosed in Yin, Y.; Alivisatos, A. P. Nature 2004, 437, 664 and Peng, Z. A.; Peng, X. J. Am. Chem. Soc. 2002, 124, 3343 the contents of both are incorporated herein by reference. In a typical synthesis, stoichiometric amounts of a copper and sulfide and/or selenide precursors may be combined under inert conditions in a coordinating solvent and heated to 150° C. under vacuum; the temperature may be reduced to 125° C. after 0.5 h. Trioctylphosphine oxide (TOPO) may be heated to 300° C., and the S and metal precursors are rapidly injected. Aliquots may be taken every 15 min over a total reaction time of 75 min. Alternatively metal chalcogenide precursors for making thin films of the present invention may be made by the process described in U.S. Pat. No. 7,563,430 B2 the contents of which are incorporated herein by reference. Alternatively metal sulfide nanoparticles useful in the present invention may be synthesized by the method disclosed in U.S. Pat. Nos. 7,455,825 and 7,651,674, the contents of which are incorporated herein by reference. Metal chalcogenide nanoparticles precursors may also be prepared by the method described in U.S. Pat. No. 7,465,352, the contents of which are incorporated herein by reference.

1) A solar cell absorber composition comprising nanoparticles,
said nanoparticles comprise a compound having the formula M^{A}ₓM^{B}_{y}M^{C}_{z}(L^{A}ₐL^{B}_{b})₄ where M^{A}, M^{B} and M^{C} comprise elements chosen from the group consisting of Fe, Co, Ni, Cu, Zn, Cd, Sn and Pb, L^{A} and L^{B} are chalcogens and
x is between 1.5 and 2.2, y and z are independently the same or different and are between 0.5 and 1.5 and (a+b)=1.

2) A solar cell absorber composition according to claim 1, wherein:
said nanoparticles comprise a compound having the formula CuₓZn_{y}Sn_{z}(SₐSe_{b})₄ where x/(y+z)=0.7 to 1.2; y/z=0.7 to 1.5 and a+b=1.

3) A solar cell absorber composition according to claim 2, wherein:
said nanoparticles are sintered.

4) A solar cell absorber composition according to claim 3, wherein:
said sintered nanoparticles comprise a compound having the formula Cu₂ZnSnSe₄, Cu₂ZnSnS₄ and Cu₂ZnSnSₓSe₄₋ₓ where 0<x<4, and combinations thereof.

5) A solar cell absorber composition according to claim 4, wherein:
the Sn_{Zn} defect centers are less than the Sn_{Cu} defect centers.

6) A solar cell absorber composition according to claim 1, wherein:
said nanoparticles comprise a compound having a direct bandgap of about 0.7 to 1.8 eV.

7) A solar cell absorber composition according to claim 2, wherein:
said nanoparticles are dispersed in an organic solvent and,
said dispersion has a viscosity between about 1-100 cP.

8) A solar cell absorber composition according to claim 2, further comprising:
a ligand attached to the compound,
said ligand comprises a compound chosen from the group consisting of alkyl phosphines, alkyl phosphine oxides, alkyl phosphonic acids, or alkyl phosphinic acids, alkyl carboxylic acids, pyridines, cyclic ethers, amines, hydrazine and alkyl hydrazines.

9) A solar cell absorber composition according to claim 8, wherein,
said ligand is pyridine.

10) A photovoltaic device, comprising:
two electrodes, at least one of which is transparent,
an absorber layer comprising nanoparticles,
and a window layer,
said nanoparticles comprise a compound having the formula
M^{A}ₓM^{B}_{y}M^{C}_{z}(L^{A}ₐL^{B}_{b})₄ where M^{A}, M^{B} and M^{C} comprise elements chosen from the group consisting of Fe, Co, Ni, Cu, Zn, Cd, Sn and Pb, L^{A} and L^{B} are chalcogens and x is between 1.5 and 2.2, y and z are independently the same or different and are between 0.5 and 1.5 and (a+b)=1.

11) A photovoltaic device according to claim 10, wherein:
said nanoparticles comprise a compound having the formula CuₓZn_{y}Sn_{z}(SₐSe_{b})₄ where x/(y+z)=0.7 to 1.2, y/z=0.7 to 1.5 and a+b=1.

12) A photovoltaic device according to claim 11, wherein:
said nanoparticles comprise a compound selected from the group consisting of Cu₂ZnSnSe₄, Cu₂ZnSnS₄ and Cu₂ZnSnSₓSe₄₋ₓ where 0<x<4, and combinations thereof.

13) A photovoltaic device according to claim 11, wherein:
said nanoparticles are sintered.

14) A photovoltaic device according to claim 13, wherein:
said sintered nanoparticles comprise a compound selected from the group consisting of Cu₂ZnSnSe₄, Cu₂ZnSnS₄ and Cu₂ZnSnSₓSe₄₋ₓ where 0<x<4, and combinations thereof.

15) A photovoltaic device according to claim 14, wherein:
the Sn defect centers are less than the Sn_{Cu} defect centers.

16) A photovoltaic device according to claim 10, wherein:
said nanoparticles comprise a compound having a direct bandgap of about 0.7 to 1.8 eV.

17) A photovoltaic device according to claim 11, wherein:
said composition has a viscosity between about 1-100 cP.

18) A photovoltaic device according to claim 11, further comprising:
a ligand attached to the compound,
said ligand is chosen from the group consisting of alkyl phosphines, alkyl phosphine oxides, alkyl phosphonic acids, or alkyl phosphinic acids, alkyl carboxylic acids, pyridines, cyclic ethers, amines and hydrazine and alkyl hydrazines.

19) A photovoltaic device according to claim 18, wherein,
said ligand is pyridine.

20) A method of making a photovoltaic device, comprising:
coating a viscous dispersion on a substrate,
said viscous dispersion comprises nanoparticles in a solvent,
said nanoparticles comprise CuₓE, where x is 1 or 2 and E is S or Se; ZnS and SnEₓ where E is S or Se and x is 1 or 2, and
sintering the nanoparticles.

21) A method of making a photovoltaic device according to claim 20, further comprising:
attaching a ligand to a nanoparticle prior to coating,
said ligand chosen from the group consisting of alkyl phosphines, alkyl phosphine oxides, alkyl phosphonic acids, or alkyl phosphinic acids, alkyl carboxylic acids, pyridines, cyclic ethers, amines and hydrazine and alkyl hydrazines.

22) A method of making a photovoltaic device according to claim 21, wherein:
said ligand and the solvent both comprise pyridine.

23) A method of making a photovoltaic device according to claim 22, wherein:
said ligand and said solvent both consist essentially of pyridine.

24) A method of making a photovoltaic device according to claim 23, wherein:
the viscosity of the dispersion is between about 1-100 cP.

25) A method of making a photovoltaic device according to claim 20, wherein:
the nanoparticles are sintered at a temperature of between about 200-600° C.

26) A method of making a photovoltaic device according to claim 20, wherein said sintering is done under a selenium atmosphere.
